(19) United States
(12) Patent Application Publication
(10) Pub. No.: US 2026/0088085 A1
(43) Pub. Date: Mar. 26, 2026

(54) OPTICAL MEMORY FOR INTEGRATED ALL-OPTICAL LOGIC

(71) Applicant: INTERNATIONAL BUSINESS MACHINES CORPORATION, Armonk, NY (US)

(72) Inventors: Darius Urbonas, Adliswil (CH); Rainer F. Mahrt, Maennedorf (CH); Thilo Hermann Curt Stoeferle, Rueschlikon (CH)

(21) Appl. No.: 18/896,309

(22) Filed: Sep. 25, 2024

(51) Int. Cl. G11C 13/00; G11C 13/04

(52) U.S. Cl. CPC G11C 13/004; G11C 13/0004; G11C 13/0061; G11C 13/048

(57) ABSTRACT

An optical processor and a method for optically processing data are described herein. The optical processor may comprise an optical pulse generator, an optical memory, and optical logic. The optical pulse generator may be configured to generate an optical interrogation pulse. The optical memory may comprise one or more memory cells. Each memory cell may comprise a phase-change material. The optical memory may be configured to direct the optical interrogation pulse at memory cells thereby generating optical readout pulses. Each optical readout pulse may correspond to a state of the phase-change material in the memory cells thereby encoding data stored in the memory cells. Each optical readout pulse may be directed to the optical logic. The optical logic may be configured to perform at least one logical operation on the data based on the readout pulses.

### BACKGROUND

Embodiments of the present disclosure relate to optical processors, and more specifically, to optical processors using optical memory.

### SUMMARY

According to embodiments of the present disclosure, optical processors and methods for optically processing data are disclosed. An optical processor system may comprise an optical pulse generator, an optical memory, and optical logic. The optical memory may comprise a plurality of memory cells. Each memory cell may comprise a phase-change material. The phase-change material may have a first state and a second state. The optical pulse generator may be configured to generate an optical interrogation pulse. The optical interrogation pulse may be directed at the optical memory. The optical memory may be configured to direct the optical interrogation pulse at one or more of the memory cells thereby generating one or more optical readout pulses. Each optical readout pulse may correspond to the state of the phase-change material in the one or more memory cells. As such, each optical readout pulse may thereby encode data stored in the one or more memory cells. Each optical readout pulse may be directed to the optical logic. The optical logic may be configured to perform at least one logical operation on the data based on the one or more optical readout pulses.

A method for optically processing data is disclosed. The method may include generating an optical interrogation pulse. The method may include directing the optical interrogation pulse at an optical memory.

### BRIEF DESCRIPTION OF THE DRAWINGS

FIG. 1 is a cross-sectional view of an optical processor, in accordance with one or more embodiments of this disclosure.

FIG. 2 is a schematic view of an optical processor, in accordance with one or more embodiments of this disclosure.

FIG. 3 is a cross-sectional view of an optical pulse generator, in accordance with one or more embodiments of this disclosure.

FIG. 4 is a cross-sectional view of exemplary optical logic, in accordance with one or more embodiments of this disclosure.

FIG. 5 is a flowchart illustrating a method for optically processing data, in accordance with one or more embodiments of this disclosure.

### DETAILED DESCRIPTION

Ensuring processors can operate at terahertz rates requires optical memory that can generate signals for logical operators at terahertz rates. In particular, performing readout at terahertz rates is necessary for applications that frequently require reading data. Electrical memory (e.g., static random-access memory and dynamic random-access memory) and optical memory (e.g., optical random-access memory and integrated optical memories) typically perform read out at megahertz and gigahertz rates, limiting the speeds of processors. As such, there is a need for optical memory capable of performing readout at terahertz rates for use in optical processors and/or waveguide filters. For example, such optical processors may include all-optical neural processors. The use of an optical pulse generator configured to generate pulses of picosecond durations and the use of a phase-change material for storing data as described herein enables terahertz readout rates.

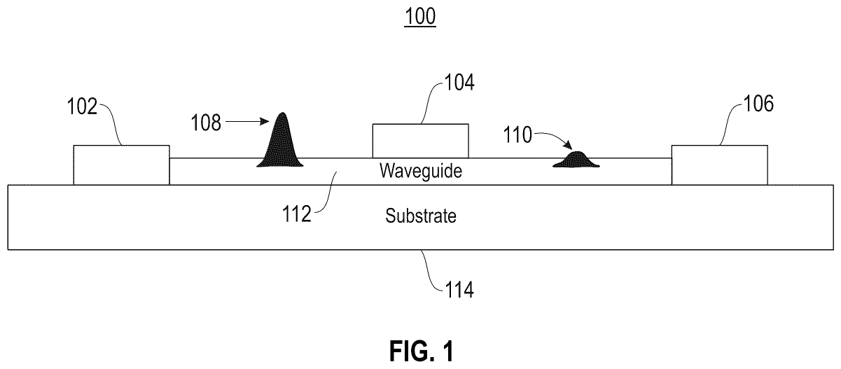

FIG. 1 is a cross-sectional view of an optical processor 100, in accordance with one or more embodiments of this disclosure. Optical processor 100 includes optical pulse generator 102, optical memory 104, optical logic 106, waveguide 112, and substrate 114. Optical pulse generator 102, waveguide 112, and optical logic 106 may be operatively coupled with substrate 114. Substrate 114 may be composed of silicon and/or another material. Waveguide 112 may be disposed between optical pulse generator 102 and optical logic 112. There may be no gap or there may be a negligible gap between optical pulse generator 102 and waveguide 112. There may be no gap or there may be a negligible gap between waveguide 112 and optical logic 106.

Waveguide 112 may be configured to facilitate transfer of pulses generated by optical pulse generator 102. The transfer of the pulses may be to optical logic 104. The pulses may be modified by waveguide 112 and/or memory cell 104 during the transfer. Waveguide 112 may be composed of silicon nitride and/or another material. By way of non-limiting example, waveguide 112 has a width of 0.45 micrometers. By way of non-limiting example, waveguide 112 has a height of 0.22 micrometers. Waveguide 112 may be a nonlinear waveguide. The pulses may be composed of one or more modes. Waveguide 112 may be configured to cut off high order modes. For example, modes of pulses higher than a given threshold may be cut off. The given threshold may be determined based on physical properties of waveguide 112. For example, the physical properties include one or more of size, shape, material, and/or other properties of the waveguide 112. An individual mode may have a cut-off wavelength or frequency. Below the cut-off wavelength (or above the cut-off frequency), the mode may not be capable of propagating through waveguide 112. The cut-off wavelength or frequency may be determined based on the physical properties of waveguide 112. Although one memory cell of optical memory 104 is illustrated here, optical memory 104 may comprise a plurality of memory cells.

The optical interrogation pulses may be directed at optical memory 104. For example, pulse 108 and pulse 110 were generated by optical pulse generator 102. Optical pulse generator 102 may be configured to generate pulses of light of picosecond durations. By way of non-limiting example, optical pulse generator 102 is configured an optical interrogation pulse. The optical interrogation pulse may be of a picosecond duration.

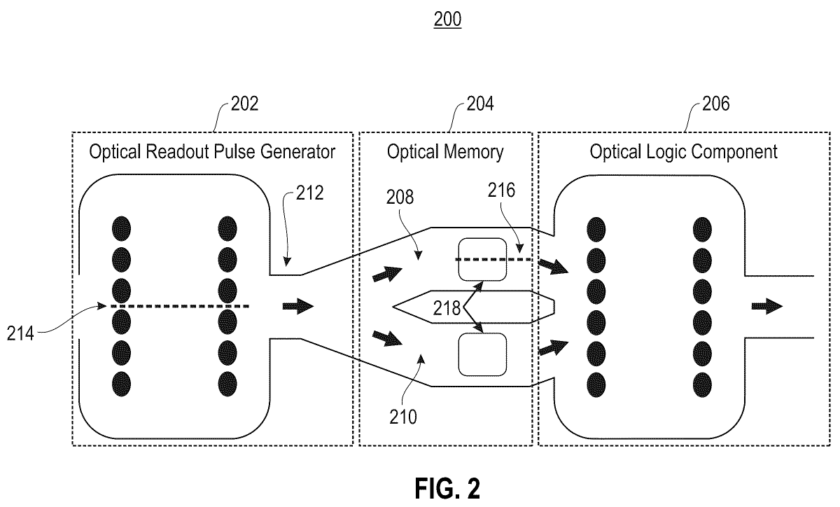

FIG. 2 is a schematic view of an optical processor 200, in accordance with one or more embodiments of this disclosure. Optical processor 200 may comprise optical pulse generator 202, optical memory 204, and optical logic 206. For example, optical pulse generator 202, optical memory 204, and optical logic 206 may be operatively coupled with waveguide 212. Waveguide 212 may be split into a plurality of pathways where optical memory 204 is operatively coupled with waveguide 212. Optical memory may comprise memory cells 214. For example, waveguide 212 is split into pathway 208 and pathway 210 within optical memory 204. Pulses generated by optical pulse generator 202 may be split across the pathways of optical memory 204. Each pathway of optical memory 204 may correspond to an individual memory cell of optical memory 204. For example, one of memory cells 218 is located on pathway 208 and another of memory cells 218 is located on pathway 210.

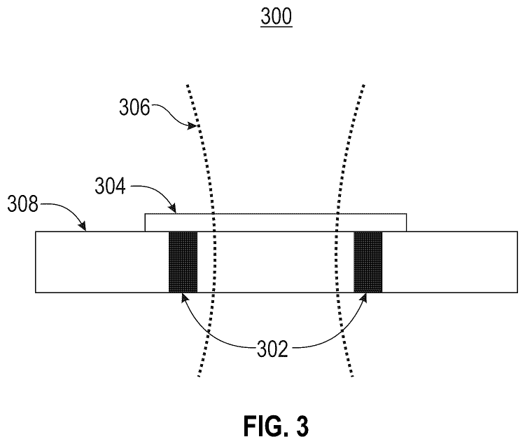

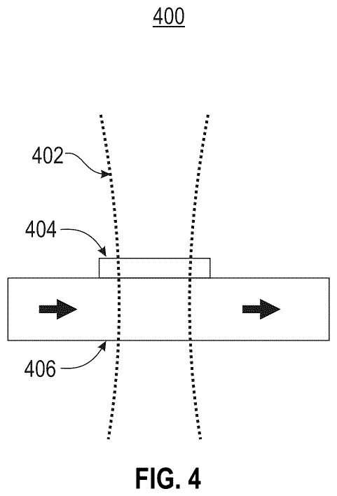

A heating means may be used to write data to individual ones of memory cells 218. Cross-sectional view 214 of a memory cell 218 may be depicted in FIG. 3 and described herein. For example, cross section 216 may be depicted in FIG. 4 and described herein.

FIG. 3 is a cross-sectional view of optical pulse generator 300. Optical pulse generator 300 may comprise a high contrast grating 302, an active material 304, a pump laser 306, and/or other components. Optical pulse generator 300 may comprise an optical cavity. In some implementations, high contrast grating 302 and active material 304 make up the optical cavity. By way of non-limiting example, high contrast grating 302 is embedded within active material 304. Pump laser 306 may generate and introduce light to active material 304. Pump laser 306 may trigger optical excitations in active material 304. The optical excitations may be strongly coupled and/or related to photonic modes of optical pulse generator 300. The optical excitations may result in exciton-polariton quasiparticles. The exciton-polariton quasiparticles may form polariton condensates. The polariton condensates may have nonlinear behavior and be used for optical pulse generation by optical pulse generator 300. High contrast grating 302 may reflect the light within optical pulse generator 300. The light may be amplified by optical pulse generator 300. The light may be directed out of optical pulse generator 300, thereby generating a pulse.

FIG. 4 is a cross-sectional view of memory cell 400, in accordance with one or more embodiments of this disclosure. Memory cell 400 may comprise a phase-change material 404. Phase-change material 404 may have a first state, a second state, and/or one or more other states. The first state may be a first phase of phase-change material 404. The second state may be a second phase of phase-change material 404. As used herein, the term “phase” may be used to refer to an aggregate state of the matter having the “phase.” The first phase may be an amorphous phase. The second phase may be a crystalline phase. By way of non-limiting example, phase-change material 404 may have a third state. The third state may be a third phase. The third phase may be a partially crystalline phase.

In some implementations, the crystalline state is associated with a set state of memory cell 400, and the amorphous state is associated with a reset state of memory cell 400. In some implementations, the crystalline state is associated with a reset state of memory cell 400, and the amorphous state is associated with a set state of memory cell 400. Phase-change material 404 may encode data stored in memory cell 400. For example, memory cell 400 stores a bit of information. The state of phase-change material 404 may encode the information stored by memory cell 400. By way of non-limiting example, phase-change material 404 has a length of 9 micrometers, a height of 50 nanometers, and/or a width of 0.4 micrometers. By way of non-limiting example, phase-change material 404 has a height of 2.5 nanometers on the waveguide.

Phase-change material 404 may have different electrical or optical properties dependent on the current state being maintained. By way of non-limiting example, phase-change material 404 has a refractive index of 3.5 and an extinction coefficient of 2.0 while maintaining the amorphous state. By way of non-limiting example, phase-change material 404 has a refractive index of 2.0 and an extinction coefficient of 3.75 while maintaining the crystalline state. In some implementations, the refractive index of phase-change material 404 is tuned using n-type doping. Phase-change material 404 may be a chalcogenide glass. By way of non-limiting example, phase-change material 404 is geranium-antimony tellurium (GeSbTe).

A pulse of light may be provided to memory cell 400 via waveguide 406. The pulse may pass through memory cell 400. The pulse may be modified as it passes through memory cell 400. Memory cell 400 may modify the pulse in accordance with the state being maintained by phase-change material 404. For example, the pulse is modified as it passes through phase-change material 404. The pulse may be modified in accordance with the refractive index and the extinction coefficient of phase-change material 404. As such, the pulse may be modified differently when phase-change material 404 is in the first state than when phase-change material 404 is in the second state. As such, the modified pulse may indicate information stored by memory cell 400. The modified pulse may be used as a seed input for optical logic 106 depicted in FIG. 1 and described herein. In some implementations, an active material with trans-cis isomerization is used in place of phase-change material 404 and/or heating component 402. In some implementations, a separate optically absorbing layer is included in place of or in addition to phase-change material 404. In such an implementation, heat transport is used to write data to the memory cell.

FIG. 4 depicts a heating component 402 configured to heat memory cell 400. Although heating component 402 is depicted here as being part of memory cell 400, that is not intended to be limiting. Heating component 402 may be included in an optical processor that includes memory cell 400. In some implementations, heating component 402 is shared across some or all memory cells of the optical processor. In such implementations, heating component 402 is configured to heat individual memory cells individually. For example, each of memory cells 218 (depicted in FIG. 2 and described herein) is heated by heating component 402 separately from each other. The heating of individual memory cells may effectuate transitions of the phase-change material of the individual memory cells between states. For example, heating memory cell 400 effectuates transition of phase-change material 404 between the first state and the second state. Heating component 402 may be configured to heat memory cell 400 and/or other memory cells at a range of intensities. In some implementations, whether phase-change material 404 transitions to the first state or to the second state is dependent on the intensity of the heating. A control component may be configured to determine an intensity for heating component 402. The intensity may be determined in accordance with data to be stored by memory cell 400.

In some implementations, heating component 402 comprises at least one laser configured to illuminate memory cell 400. The illumination of memory cell 400 may effectuate heating of phase-change material 404. In some implementations, heating component 402 comprises a resistive heating element. By way of non-limiting example, the resistive heating element is disposed above and/or below phase-change material 404. The resistive heating element may heat phase-change material 404. In some implementations, transitions of phase-change material 404 between the crystalline state and the amorphous state are non-volatile. In some implementations, heating component 402 comprises a laser and a waveguide. The waveguide may end at, cross, be over, and/or be under phase-change material 404. By way of non-limiting example, the waveguide is coupled with phase-change material 404 using evanescent coupling.

In some implementations, heating component 402 comprises an electric field generator. In such implementations, phase-change material 404 may be a non-centrosymmetric material. For example, phase-change material 404 is a crystal material or a compound semiconductor. The electric field generator may be configured to generate a static electric field. By way of non-limiting example, the static electric field is generated by coupling actively tuned resonators. The static electric field may control Pockels effect. As such, the static electric field may be used to modify phase-change material 404.

Referring back to FIG. 1, optical logic 106 may comprise one or more amplifiers and/or logic gates. In some implementations, the one or more amplifiers and/or logic gates comprise one or more optical cavities. For example, each amplifier or logic gate may comprise an optical cavity. Optical logic 106 may comprise one amplifier or logic gate as depicted in FIG. 1.

Optical logic 106 may be configured to perform at least one logical operation on the data stored by memory cell 104. More generally, the phrase optical logic is used herein to refer to one or more optical components that are configured to perform digital computation through the composition of one or more logical operations. The at least one logical operation may be performed based on the one or more optical readout pulses. Performing the at least one logical operation may include receiving an input pulse. In some implementations, the input pulse is divided and provided to multiple optical cavities of optical logic 106 at the same time or substantially at the same time. In some implementations, the input pulse may be modified by a first optical cavity of optical logic 106 then passed to another optical cavity of optical logic 106. Optical logic 106 may be configured to modify the input pulse at the one or more optical cavities. Optical logic 106 may be configured to effectuate transmission of the modified input pulse through the optical logic. Optical logic 106 may perform logical operations using seeded polariton condensates.

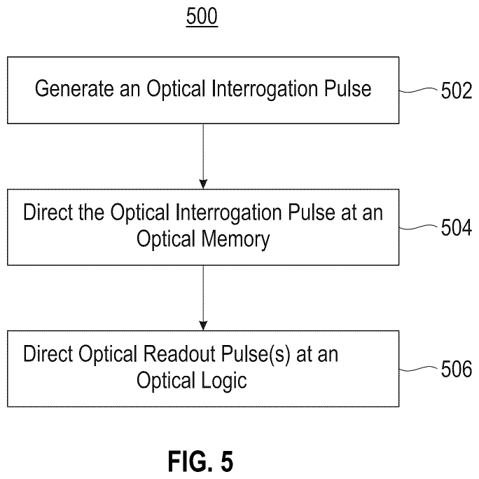

FIG. 5 is a flowchart illustrating an exemplary method 500 for optically processing data. The operations of method 500 presented below are intended to be illustrative. In some implementations, method 500 may be accomplished with one or more additional operations not described and/or without one or more of the operations discussed. Additionally, the order in which the operations of method 500 are illustrated in FIG. 5 and described below is not intended to be limiting.

In some implementations, method 500 may be implemented in one or more processing devices (e.g., a digital processor, an analog processor, a digital circuit designed to process information, a state machine, and/or other mechanisms for electronically processing information). The one or more processing devices may include one or more devices configured through hardware, firmware, and/or software to be specifically designed for execution of one or more of the operations of method 500.

Operation 502 may include generating an optical interrogation pulse. The optical interrogation pulse may be generated by an optical pulse generator. Operation 504 may include directing the optical interrogation pulse at an optical memory. The optical memory may comprise a plurality of memory cells. Each memory cell may comprise a phase-change material. The phase-change material may have a first state and a second state. One or more optical readout pulses may be generated responsive to the optical interrogation pulse being directed at the optical memory. Each optical readout pulse may correspond to the state of the phase-change material in the one or more memory cells. As such, each optical readout pulse may encode data stored in the one or more memory cells. In some implementations, method 500 includes operation 506. Operation 506 includes directing the one or more optical readout pulses at an optical logic configured to perform at least one logical operation on the data. The optical logic may perform the at least one logical operation based on the one or more optical readout pulses.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Reference has been made in detail herein to the exemplary embodiments of the present disclosure, examples of which are illustrated in the accompanying drawings. The systems, devices, and methods disclosed herein are described in detail by way of examples, and with reference to the figures. The examples discussed herein are examples only and are provided to assist in the explanation of the apparatuses, devices, systems, and methods described herein. None of the features or components shown in the drawings or discussed below should be taken as mandatory for any specific implementation of any of these devices, systems, or methods unless specifically designated as mandatory.

For any methods described, regardless of whether the method is described in conjunction with a flow diagram, it should be understood that unless otherwise specified or required by context, any explicit or implicit ordering of steps performed in the execution of a method does not imply that those steps must be performed in the order presented but instead may be performed in a different order or in parallel.

As used herein, the term “exemplary” is used in the sense of “example,” rather than “ideal.” Moreover, the terms “a” and “an” herein do not denote a limitation of quantity, but rather denote the presence of one or more of the referenced items.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An optical processor comprising:
an optical pulse generator;
an optical memory comprising a plurality of memory cells, each memory cell comprising a phase-change material, the phase-change material having a first state and a second state; and
optical logic,
wherein:
the optical pulse generator is configured to generate an optical interrogation pulse, the optical interrogation pulse being directed at the optical memory,
the optical memory is configured to direct the optical interrogation pulse at one or more of the memory cells thereby generating one or more optical readout pulses, each optical readout pulse corresponding to the state of the phase-change material in the one or more memory cells, thereby encoding data stored in the one or more memory cells, each optical readout pulse being directed to the optical logic, and
the optical logic is configured to, based on the one or more optical readout pulses, perform at least one logical operation on the data.

2. The optical processor of claim 1, wherein the optical logic is configured to:
receive the one or more optical readout pulses.

3. The optical processor of claim 1, wherein the optical pulse generator is configured to generate interrogation pulses of picosecond durations.

4. The optical processor of claim 1, further comprising a heating means configured to heat the one or more memory cells.

5. The optical processor of claim 4, wherein the heating means comprises at least one laser configured to illuminate the one or more memory cells.

6. The optical processor of claim 5, wherein the heating means comprises at least one resistive heating element configured to heat the one or more memory cells.

7. The optical processor of claim 1, wherein the optical processor further comprises a waveguide, and wherein the optical pulse generator, the optical memory, and the optical logic are in optical communication through the waveguide.

8. The optical processor of claim 1, wherein the first state is a first phase of the phase-change material, and the second state is a second phase of the phase-change material.

9. The optical processor of claim 8, wherein the first phase is an amorphous phase, and the second phase is a crystalline phase.

10. The optical processor of claim 1, wherein the optical pulse generator comprises a high contrast grating, an active material, and a pump laser.

11. A method for optically processing data, the method comprising:
generating an optical interrogation pulse; and
directing the optical interrogation pulse at an optical memory, the optical memory comprising a plurality of memory cells, each memory cell comprising a phase-change material, the phase-change material having a first state and a second state, thereby generating one or more optical readout pulses, each optical readout pulse corresponding to the state of the phase-change material in the one or more memory cells, thereby encoding data stored in the one or more memory cells.

12. The method of claim 11, further comprising:
directing the one or more optical readout pulses at optical logic configured to, based on the one or more optical readout pulses, perform at least one logical operation on the data.

13. The method of claim 11, wherein the optical pulse generator is configured to generate interrogation pulses of picosecond durations.

14. The method of claim 11, further comprising heating the one or more memory cells.

15. The method of claim 14, wherein heating comprises illuminating the one or more memory cells by a laser.

16. The method of claim 15, wherein heating comprises heating the one or more memory cells by a resistive element.

17. The method of claim 11, wherein the first state is a first phase of the phase-change material, and the second state is a second phase of the phase-change material.

18. The method of claim 17, wherein the first phase is an amorphous phase, and the second phase is a crystalline phase.
